(19) United States
(12) Patent Application Publication
(10) Pub. No.: US 2024/0333214 A1
(43) Pub. Date: Oct. 3, 2024

(54) OSCILLATION CIRCUIT AND SEMICONDUCTOR INTEGRATED CIRCUIT

(71) Applicant: ROHM Co., LTD., Kyoto (JP)

(72) Inventors: Nozomu Koja, Kyoto (JP); Kenichi Motoki, Kyoto (JP)

(21) Appl. No.: 18/615,496

(22) Filed: Mar. 25, 2024

(30) Foreign Application Priority Data
Mar. 29, 2023 (JP) 2023-054391

(51) Int. Cl. H03B 5/36; H03B 5/12

(52) U.S. Cl. CPC H03B 5/364; H03B 5/1228; H03B 2200/0082

(57) ABSTRACT

Provided is an oscillation circuit including a first terminal to which a first end of a crystal resonator is to be connected, a second terminal to which a second end of the crystal resonator is to be connected, a first resistor connected between the first terminal and the second terminal, a first transistor that is an N-channel transistor whose source is grounded, whose gate is connected to the first terminal, and whose drain is connected to the second terminal, a second transistor that is a P-channel transistor whose drain is connected to the drain of the first transistor, a third transistor that is a P-channel transistor biased by a constant current. A first state in which the first transistor and the second transistor operate as an inverter circuit, and a second state in which the second transistor and the third transistor operate as a current mirror circuit are switchable.

### CROSS REFERENCE TO RELATED APPLICATIONS

This application claims priority benefit of Japanese Patent Application No. JP 2023-054391 filed in the Japan Patent Office on Mar. 29, 2023. Each of the above-referenced applications is hereby incorporated herein by reference in its entirety.

### BACKGROUND

The present disclosure relates to an oscillation circuit.

In semiconductor integrated circuits, crystal oscillators are used to generate clock signals with high precision frequencies. The crystal oscillator includes a crystal resonator externally attached to a semiconductor integrated circuit and an oscillation circuit integrated into the semiconductor integrated circuit.

### BRIEF DESCRIPTION OF THE DRAWINGS

FIG. 1 is a circuit diagram of an oscillator including an oscillation circuit according to an embodiment;

FIG. 2 is a circuit diagram illustrating a specific configuration example of the oscillation circuit;

FIG. 3 is an equivalent circuit diagram of a crystal oscillator in a first state;

FIG. 4 is an equivalent circuit diagram of the crystal oscillator in a second state;

FIG. 5 is an operation waveform diagram when the crystal oscillator is started while being fixed in the second state; and

FIG. 6 is an operation waveform diagram of the crystal oscillator according to the embodiment.

### DETAILED DESCRIPTION

### Overview of Embodiment

An overview of some exemplary embodiments of the present disclosure will be described. This overview is intended to provide a simplified description of some concepts of one or more embodiments in order to provide a basic understanding of the embodiments as an introduction to the more detailed description to be presented later, and does not limit the size of the disclosure. This overview is not a comprehensive overview of all conceivable embodiments and is not intended to identify key elements of all embodiments nor to delineate the scope of any or all aspects. For convenience, “an embodiment” may be used to refer to one embodiment (example or modification) or a plurality of embodiments (examples or modifications) disclosed in the present specification.

The oscillation circuit according to an embodiment is provided with a first terminal to which a first end of a crystal resonator is to be connected, a second terminal to which a second end of the crystal resonator is to be connected, a first resistor connected between the first terminal and the second terminal, a first transistor that is an N-channel transistor whose source is grounded, whose gate is connected to the first terminal, and whose drain is connected to the second terminal, and a second transistor that is a P-channel transistor whose drain is connected to the drain of the first transistor, and a third transistor that is a P-channel transistor provided on a constant current path. The oscillation circuit is configured such that a first state in which the first transistor and the second transistor operate as an inverter circuit, and a second state in which the second transistor and the third transistor operate as a current mirror circuit are switchable.

According to this aspect, since the first transistor and the second transistor constitute an inverter by the selection of the first state during the first period after the start of start-up, the start-up rate can be increased and the start-up time can be shortened. In a steady oscillation state after completion of start-up, power consumption can be suppressed by selecting the second state for biasing the second transistor by using the third transistor so as to limit the current flowing through the first transistor.

In an embodiment, the oscillation circuit may further include a first switch connected between the gate of the first transistor and the gate of the second transistor. In the first period, by turning on the first switch, the first transistor and the second transistor can be made to operate as an inverter.

In an embodiment, the oscillation circuit may further include a second switch connected between the gate of the second transistor and the gate of the third transistor. In the second period, by turning on the second switch, the second transistor and the third transistor can be made to operate as a current mirror circuit.

A semiconductor integrated circuit according to an embodiment may include any of the oscillation circuits described above.

### Embodiments

Hereinafter, preferred embodiments will be described with reference to the drawings. Identical or equivalent components, members, and processes illustrated in each drawing are designated by the same reference numerals, and redundant descriptions will be omitted as appropriate. Further, the embodiments are illustrative rather than limiting the disclosure, and all features and combinations thereof described in the embodiments are not necessarily essential to the disclosure.

In the present specification, “a state in which member A is connected to member B” refers to not only a case where member A and member B are physically and directly connected, but also a case where member A and member B are indirectly connected via other members that do not substantially affect the electrical connection state nor impair the functions and effects achieved by their combination.

Similarly, “a state in which member C is provided between member A and member B” refers to not only a case where member A and member C or member B and member C are directly connected, but also the cases where they are indirectly connected via other members that do not substantially affect the electrical connection state nor impair the functions and effects achieved by their combination.

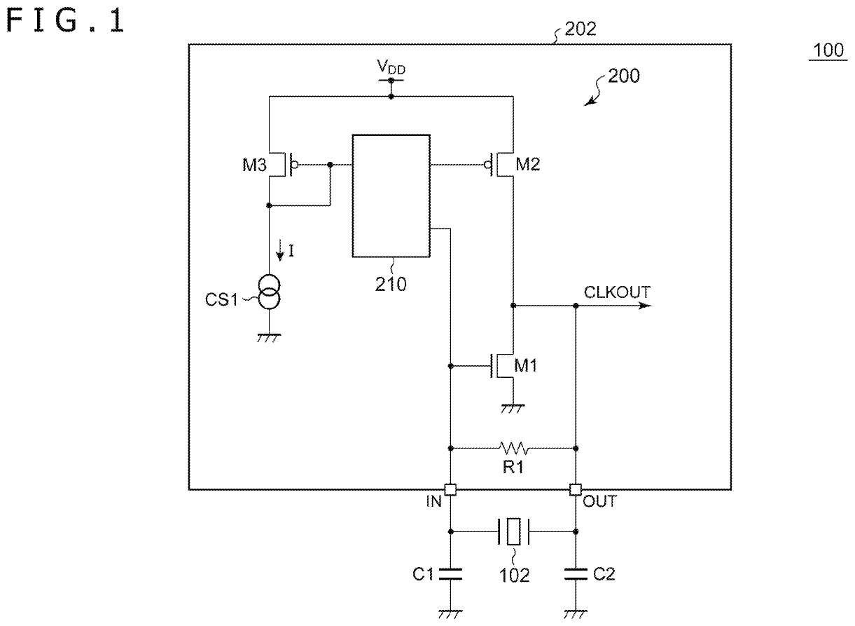

FIG. 1 is a circuit diagram of a crystal oscillator 100 including an oscillation circuit 200 according to an embodiment. The crystal oscillator 100 includes a crystal resonator 102 and the oscillation circuit 200.

The oscillation circuit 200 is integrated into a semiconductor integrated circuit 202. The functions of the semiconductor integrated circuit 202 are not particularly limited, and the semiconductor integrated circuit 202 may be an application specific integrated circuit (ASIC) such as a power supply IC or a motor driver, or a microcomputer.

The semiconductor integrated circuit 202 has a first terminal IN and a second terminal OUT. One end of the crystal resonator 102, which is an external component, is connected to the first terminal IN, and the other end of the crystal resonator 102 is connected to the second terminal OUT. Further, external capacitors C1 and C2 are connected to the first terminal IN and the second terminal OUT, respectively.

The oscillation circuit 200 includes a first transistor M1, a second transistor M2, a third transistor M3, a first resistor R1, and a switching circuit 210.

The first resistor R1 is connected between the first terminal IN and the second terminal OUT. The first transistor M1 is an N-channel metal oxide semiconductor field effect transistor (MOSFET). The source of the first transistor M1 is grounded, its gate is connected to the first terminal IN, and the drain is connected to the second terminal OUT.

The second transistor M2 is a P-channel MOSFET, and its drain is connected to the drain of the first transistor M1.

The third transistor M3 is a transistor of the same type as the second transistor M2, namely a P-channel MOSFET, and its gate and drain are connected. A current source CS1 is connected to the drain of the third transistor M3.

The oscillation circuit 200 is configured to be able to switch between (i) a state φ1 in which the first transistor M1 and the second transistor M2 operate as an inverter circuit, and (ii) a state φ2 in which the second transistor M2 and the third transistor M3 operate as a current mirror circuit.

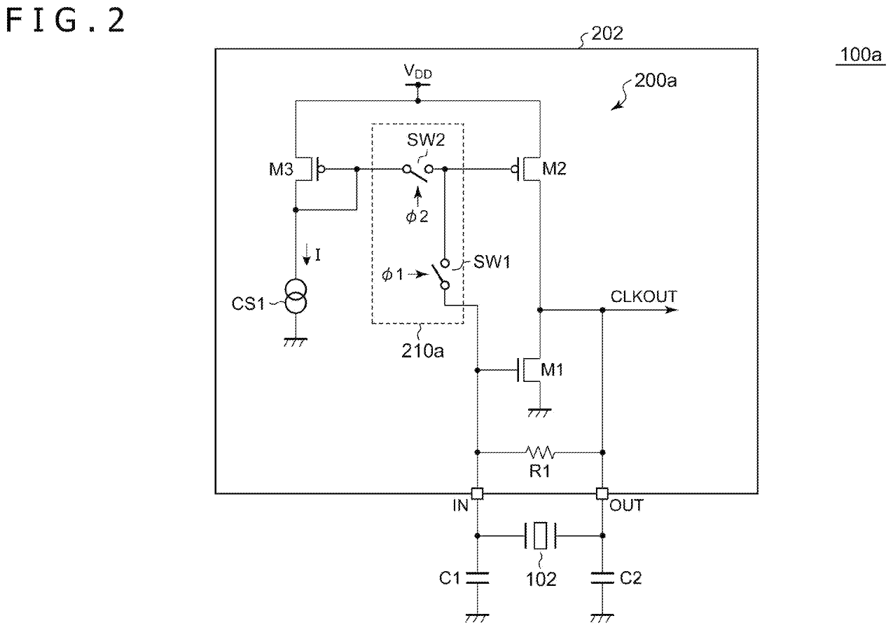

FIG. 2 is a circuit diagram illustrating a specific configuration example (200a) of the oscillation circuit 200. A switching circuit 210a includes a first switch SW1 and a second switch SW2.

The first switch SW1 is connected between the gate of the first transistor M1 and the gate of the second transistor M2. When the first switch SW1 is turned on, the gates of the first transistor M1 and the second transistor M2 are connected to each other to form an inverter circuit.

The second switch SW2 is connected between the gate of the second transistor M2 and the gate of the third transistor M3. When the second switch SW2 is turned on, the gates of the second transistor M2 and the third transistor M3 are connected to each other to form a current mirror circuit.

Incidentally, it is understood that the configuration of the switching circuit 210a illustrated here is only an example, and various modifications exist.

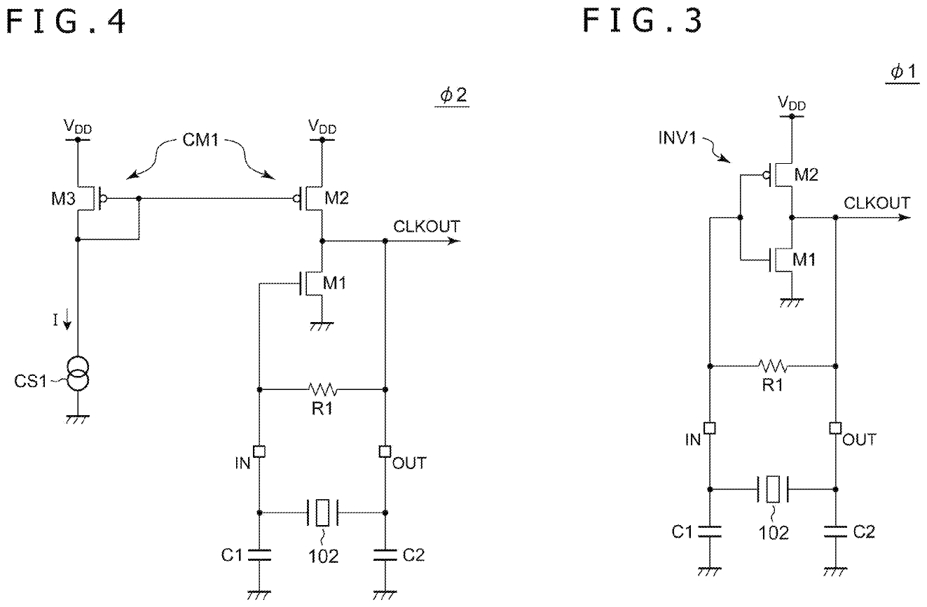

FIG. 3 is an equivalent circuit diagram of a crystal oscillator 100a in the first state 1. The crystal oscillator 100a operates in the first state φ1 during the first period from the start of start-up. The first transistor M1 and the second transistor M2 constitute an inverter circuit INV1.

FIG. 4 is an equivalent circuit diagram of the crystal oscillator 100a in the second state 92. The crystal oscillator 100a operates in the second state 42 during the second period from the start of start-up. The second transistor M2 and the third transistor M3 constitute a current mirror circuit CM1, and a current that is m times as large as the current generated by the current source CS1 (m is the current mirror ratio) flows through the second transistor M2, and is supplied to the first transistor M1.

The configuration of the crystal oscillator 100 has been described above. Next, its operation will be described.

For comparison, described is the operation when the crystal oscillator 100 is started with the crystal oscillator 100 fixed in the second state 42 with priority given to suppressing power consumption.

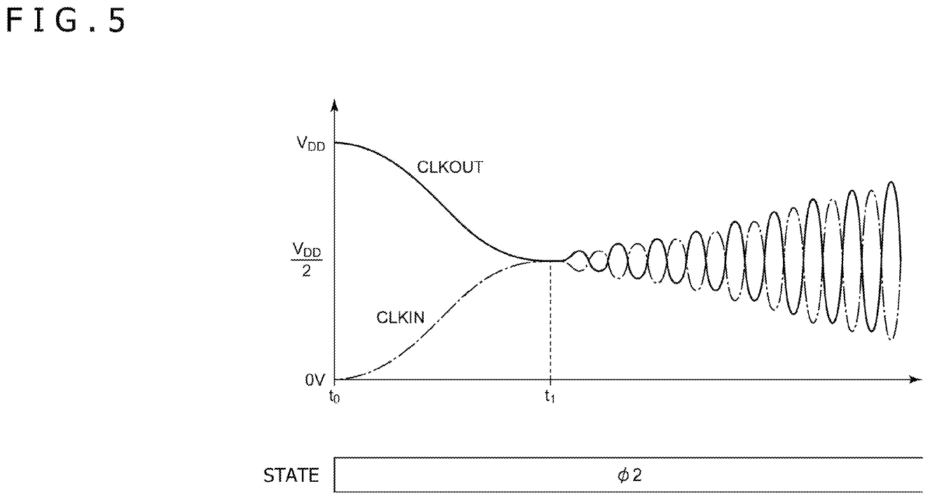

FIG. 5 is an operation waveform diagram at start-up while the second state φ2 is fixed. FIG. 5 illustrates a voltage VIN at the first terminal IN and a voltage CLKOUT at the second terminal OUT. At time to at the start of start-up, the first transistor M1 is off, the output signal CLKOUT is a power supply voltage V_{DD}, and the input voltage VIN is 0 V. The input signal VIN and the output signal CLKOUT are complementary signals.

At the start of start-up, the input signal VIN increases toward the midpoint voltage V_{DD}/2 of the power supply voltage V_{DD}, and the output signal CLKOUT decreases toward the midpoint voltage V_{DD}/2. In the second state, since the current supplied to the first transistor M1 by the second transistor M2 is limited, the time required for the input signal VIN and the output signal CLKOUT to converge to the midpoint voltage V_{DD}/2 is increased, and it takes a long time to start oscillation (t₁). Furthermore, after the start of oscillation, the amplitudes of the input signal VIN and the output signal CLKOUT increase with time, but if the current supply capability of the second transistor M2 is low, since a rate of increase in the amplitude is slow, it also takes a long time to output a rectangular wave clock signal CLK.

Next, the operation in the case of switching the state of the crystal oscillator 100 will be described.

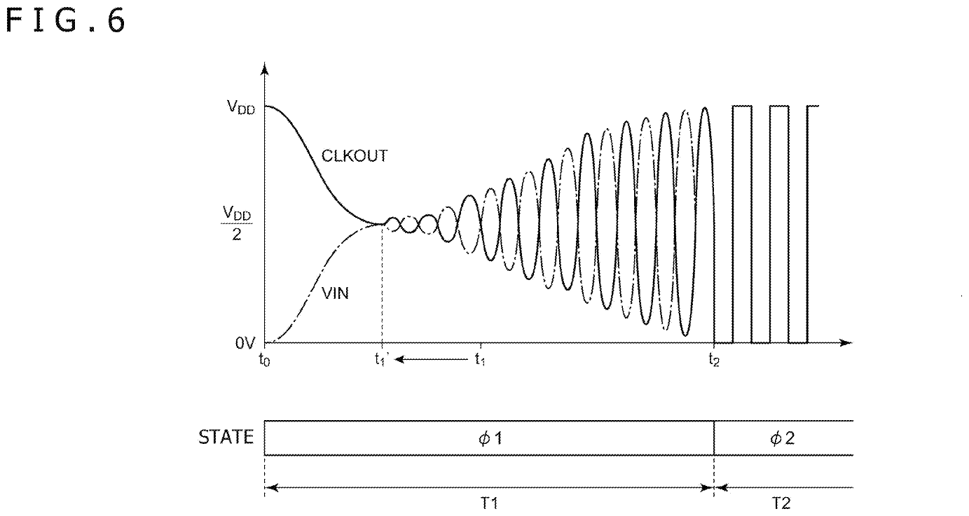

FIG. 6 is an operation waveform diagram of the crystal oscillator 100 according to the embodiment. The first state φ1 is set during the first period T1 after the start of start-up. In the first state φ1, since the gate voltage of the second transistor M2 is lower than the voltage level in the second state φ2, the second transistor M2 can be turned on more strongly, and the current supply capability of the second transistor M2 is increased. As a result, the operating rate of the first transistor M1 increases, and the input signal VIN and output signal CLKOUT converge to the midpoint voltage V_{DD}/2 in a short time, and then oscillation operation starts at time t₁′ earlier than time t₁ in FIG. 5.

Furthermore, since the current supply capability of the second transistor M2 is high, the rate of increase in amplitude is faster than the rate of increase in FIG. 5. When the amplitude reaches the power supply voltage V_{DD} at time t₂, a rectangular wave clock signal is output, and start-up of the crystal oscillator 100 is completed. During the second period after the start-up of the crystal oscillator 100 is completed, the state is switched to the second state φ2. This limits the current flowing through the first transistor M1, and reduces the current consumption of the crystal oscillator 100 in a steady oscillation state. Note that although here, the state is switched with the time t₂ at which the rectangular wave clock signal CLKOUT begins to be generated as the completion of start-up, the timing of switching is not particularly limited.

According to this oscillation circuit 200, by switching between the first state φ1 and the second state φ2, the start-up time can be shortened while an increase in current consumption is suppressed.

The embodiments described by using specific terms merely illustrate the principles and applications of the present disclosure, and the embodiments allows many variations and changes in arrangement without departing from the spirit of the present disclosure as defined in the scope of the claims.

### (Supplementary Note)

The following technology is disclosed in the present specification.

### (Item 1)

An oscillation circuit including:
a first terminal to which a first end of a crystal resonator is to be connected;
a second terminal to which a second end of the crystal resonator is to be connected;
a first resistor connected between the first terminal and the second terminal;
a first transistor that is an N-channel transistor whose source is grounded, whose gate is connected to the first terminal, and whose drain is connected to the second terminal;
a second transistor that is a P-channel transistor whose drain is connected to the drain of the first transistor;
a third transistor that is a P-channel transistor provided on a constant current path, in which
a first state in which the first transistor and the second transistor operate as an inverter circuit, and a second state in which the second transistor and the third transistor operate as a current mirror circuit are switchable.

### (Item 2)

The oscillation circuit according to Item 1, further including:
a first switch connected between the gate of the first transistor and a gate of the second transistor.

### (Item 3)

The oscillation circuit according to Item 1 or 2, further including:
a second switch connected between a gate of the second transistor and a gate of the third transistor.

### (Item 4)

A semiconductor integrated circuit including: the oscillation circuit according to any one of Item 1 to Item 3.

According to an aspect of the present disclosure, start-up time can be shortened while current consumption is suppressed.

What is claimed is:

1. An oscillation circuit comprising:
a first terminal to which a first end of a crystal resonator is to be connected;
a second terminal to which a second end of the crystal resonator is to be connected;
a first resistor connected between the first terminal and the second terminal;
a first transistor that is an N-channel transistor whose source is grounded, whose gate is connected to the first terminal, and whose drain is connected to the second terminal;
a second transistor that is a P-channel transistor whose drain is connected to the drain of the first transistor;
a third transistor that is a P-channel transistor biased by a constant current, wherein
a first state in which the first transistor and the second transistor operate as an inverter circuit, and a second state in which the second transistor and the third transistor operate as a current mirror circuit are switchable.

2. The oscillation circuit according to claim 1, further comprising:
a first switch connected between the gate of the first transistor and a gate of the second transistor.

3. The oscillation circuit according to claim 1, further comprising:
a second switch connected between a gate of the second transistor and a gate of the third transistor.

4. A semiconductor integrated circuit comprising:
the oscillation circuit according to claim 1.
